(19) United States
(12) Patent Application Publication
(10) Pub. No.: US 2026/0191055 A1
(43) Pub. Date: Jul. 2, 2026

(54) SEMICONDUCTOR DEVICE AND METHOD FOR FORMING THE SAME

(71) Applicant: STATS ChipPAC Management Pte. Ltd., Singapore (SG)

(72) Inventors: HeungKyu KWON, Gyeonggi-do (KR); YoungCheol KIM, Gyeonggi-do (KR); JingWan KIM, Incheon (KR); JungHwan JANG, Incheon (KR); KyungHan RYU, Incheon (KR); KiRak SON, Incheon (KR); DaeHo KIM, Incheon (KR); SangJin LEE, Seoul (KR); JongYun CHOI, Gyeonggi-do (KR); DongHi LEE, Incheon (KR); SooMin YOU, Incheon (KR); Hyun CHO, Incheon (KR)

(21) Appl. No.: 19/405,439

(22) Filed: Dec. 2, 2025

(30) Foreign Application Priority Data
Dec. 27, 2024 (CN) 202411952990.9

(51) Int. Cl. H10W 70/65; H10W 74/10; H10W 90/00

(52) U.S. Cl. CPC H10W 70/65; H10W 74/121; H10W 90/7295

(57) ABSTRACT

A semiconductor device and a method for forming the same are provided. The semiconductor device may include: a first redistribution layer (RDL) having a first side and a second side opposite to the first side; at least one electronic component attached on the first side of the first RDL; a photonic component attached on the second side of the first RDL; a first plurality of conductive bumps formed on the second side of the first RDL and electrically coupled with the first RDL; a second RDL having a first side and a second side opposite to the first side, wherein the first side of the second RDL is electrically coupled with the first plurality of conductive bumps; a second plurality of conductive bumps formed on the second side of the second RDL and electrically coupled with the second RDL.

### TECHNICAL FIELD

The present application generally relates to semiconductor technology, and more particularly, to a semiconductor device and A method for forming the same.

### BACKGROUND OF THE INVENTION

The semiconductor industry is constantly faced with complex integration challenges as consumers want their electronics to be smaller, faster and higher performance with more and more functionalities packed into a single device. One of the solutions is System-in-Package (SiP). SiP is a functional electronic system or sub-system that includes in a single package two or more heterogeneous semiconductor dice, such as a logic chip, a memory, integrated passive devices (IPD), RF filters, sensors, heat sinks, or antennas. Recently, photonic semiconductor devices, which are capable of transmitting or receiving signals via light, are becoming more and more common. However, the options for packaging photonic semiconductor devices into SiP have heretofore been limited and unsatisfactory in many ways.

Therefore, a need exists for an improved photonic semiconductor package.

### SUMMARY OF THE INVENTION

An objective of the present application is to provide an improved photonic semiconductor package.

According to an aspect of the present application, a semiconductor device is provided. The semiconductor device may include: a first redistribution layer (RDL) having a first side and a second side opposite to the first side; at least one electronic component attached on the first side of the first RDL; a photonic component attached on the second side of the first RDL; a first plurality of conductive bumps formed on the second side of the first RDL and electrically coupled with the first RDL; a second RDL having a first side and a second side opposite to the first side, wherein the first side of the second RDL is electrically coupled with the first plurality of conductive bumps; a second plurality of conductive bumps formed on the second side of the second RDL and electrically coupled with the second RDL.

According to another aspect of the present application, a method for forming a semiconductor device is provided. The method may include: providing a carrier; forming a first redistribution layer (RDL) on the carrier, the first RDL having a first side and a second side opposite to the first side; attaching at least one electronic component on the first side of the first RDL; forming a first encapsulant on the first side of the first RDL to encapsulate the at least one electronic component; forming a first plurality of conductive bumps on the second side of the first RDL to electrically couple with the first RDL; forming a through hole through the first encapsulant and the first RDL; providing a photonic assembly including a photonic component and a glass lens attached on the photonic component; attaching the photonic component on the second side of the first RDL with the glass lens extending through the through hole; coupling the first plurality of conductive bumps to a first side of a second RDL; and forming a second plurality of conductive bumps on a second side of the second RDL to electrically couple with the second RDL, wherein the second side of the second RDL is opposite to the first side of the second RDL.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a cross-sectional view illustrating a semiconductor device according to an embodiment of the present application.

FIGS. 2A to 2K are cross-sectional views illustrating various steps of a method for forming a semiconductor device according to an embodiment of the present application.

FIGS. 3A to 3F are top views illustrating various steps of a method for forming a photonic assembly according to an embodiment of the present application.

FIGS. 4A to 4F are top views illustrating various steps of a method for forming a photonic assembly according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

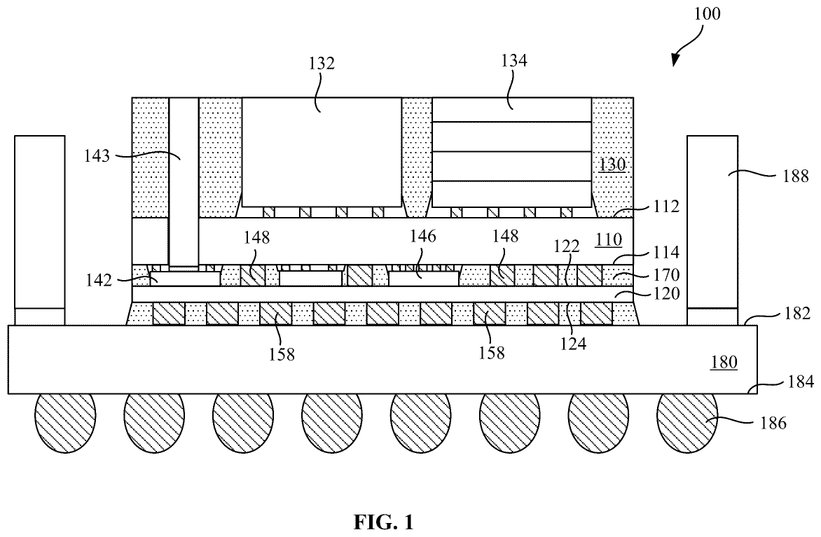

Referring to FIG. 1, a cross-sectional view of a semiconductor device 100 is illustrated according to an embodiment of the present application.

The semiconductor device 100 may include a first redistribution layer (RDL) 110 having a first side 112 and a second side 114 opposite to the first side 112. At least one electronic component is attached on the first side 112 of the first RDL 110, and a photonic component 142 attached on the second side 114 of the first RDL 110. A first plurality of conductive bumps 148 are formed on the second side 114 of the first RDL 110 and are electrically coupled with the first RDL 110. A second RDL 120 is electrically coupled with the first plurality of conductive bumps 148, and the second RDL 120 has a first side 122 and a second side 124 opposite to the first side 122. A second plurality of conductive bumps 158 are formed on the second side 124 of the second RDL 120 and are electrically coupled with the second RDL 120.

The first RDL 110 may include one or more dielectric layers and one or more conductive layers between and through dielectric layers. The conductive layers may define pads, traces and plugs through which electrical signals or voltages can be distributed horizontally and vertically across the redistribution layer. For example, the conductive layers of the first RDL 110 may form a plurality of contact pads on the first side 112 of the first RDL 110 and also form a plurality of contact pads on the second side 114 of the first RDL 110. It could be understood that, the first RDL 110 may be implemented in various structures and types, and aspects of the present application are not limited thereto.

In the example shown in FIG. 1, the at least one electronic component attached on the first side 112 of the first RDL 110 includes a first electronic component 132 and a second electronic component 134. The first electronic component 132 may be System-of-Chip (SoC) die, and the second electronic component 134 may be a memory die, for example, a high-bandwidth memory (HBM) die, a Dynamic Random Access Memory (DRAM) die, etc. The SoC die may include a semiconductor active device, such as a logic SoC, a logic die, a logic chip, or the like. The SoC die is laterally adjacent to the memory die. In some embodiments, a thickness of the SoC die is substantially the same as that of the memory die. In some embodiments, both the SoC die and the memory die are flip-chip bonded to the first side 112 of the first RDL 110.

In some embodiments, an underfill may be formed between the first electronic component 132 and the first side 112 of the first RDL 110, and between the second electronic component 134 and the first side 112 of the first RDL 110, to encapsulate the conductive bumps therebetween. The underfill may include a non-conductive paste (NCP), a molded underfill (MUF), a non-conductive film (NCF), an underfill encapsulant, or a polymer composite material, such as epoxy resin, epoxy acrylate, or polymer with or without a filler. The underfill may provide mechanical support to the first electronic component 132 and the second electronic component 134, helping to mitigate the risk of crack or delamination due to differential thermal expansion between the first electronic component 132 or the second electronic component 134 and the first RDL 110.

The photonic component 142 is attached on the second side 114 of the first RDL 110. The photonic component 142 may be a photonic integrated circuit (PIC), which has the capability to transmit and/or receive light signals. The PIC may be fabricated on a substrate of silicon, silica, or a nonlinear crystal material such as lithium niobate (LiNbO₃). For example, the PIC may include optical components such as waveguides, lasers, polarizers, and phase shifters, and can be used in areas such as optical fiber communications, optical metrology, quantum computing etc. In some embodiments, an underfill may be formed between the photonic component 142 and the second side 114 of the first RDL 110.

In some embodiments, as shown in FIG. 1, a glass lens 143, such as a fiber optic or a similar connector, is coupled with the photonic component 142. The glass lens 143 can carry light signals to and/or from the photonic component 142. For example, the glass lens 143 may be formed in a through hole extending through the first RDL 110 and optically coupled with a top side of the photonic component 142 via a transparent adhesive or a transparent die attach film (DAF). A first encapsulant 130 may be formed on the first side 112 of the first RDL 110 and may cover the first electronic component 132 and the second electronic component 134. In some examples, the first encapsulant 130 may cover the top and lateral surfaces of the first electronic component 132 and the second electronic component 134. In other examples, the first encapsulant 130 may only cover the lateral surfaces of the first electronic component 132 and the second electronic component 134. A through hole may be formed in the first encapsulant 130. The through hole may have a cross-sectional area larger than that of the glass lens 143, such that the glass lens 143 can be inserted into the through hole and is exposed from a top surface of the first encapsulant 130. The first encapsulant 130 may be made of a polymer composite material, such as epoxy resin with filler, epoxy acrylate with filler, or polymer with proper filler, but the scope of this application is not limited thereto. The glass lens 143 may penetrate through the first encapsulant 130 by extending through the through hole, and at least a top surface of the glass lens 143 is exposed from the first encapsulant 130, such that the glass lens 143 transmit light signals to and/or from the outside.

Continuing referring to FIG. 1, at least one bridge die 146 is attached on the second side 114 of the first RDL 110 and configured for electrically coupling the first electronic component 132 with the second electronic component 134. The bridge die 146 is placed over and electrically connected to the contact pads formed on the second side 114 of the first RDL 110 via conductive bumps. In other words, the first electronic component 132 and the second electronic component 134 are electrically connected through the first RDL 110, the conductive bumps and the bridge die 146. In some embodiments, the bridge die 146 may be made of semiconductor material, glass, or organic materials with redistribution layers or wiring patterns formed therein. Preferably, the bridge die 146 is a silicon-based interposer (also known as a silicon bridge). The bridge die 146 may be fabricated using any suitable IC manufacturing processes and can offer various advantages. For example, the bridge die 146 can support fine pitches for through-silicon vias (TSVs) and traces used in signal and power distribution, and may have a thermal expansion coefficient which can match that of the semiconductor die it is in contact with. For example, the bridge die 146 may include a semiconductor layer, a plurality of wiring patterns formed on the semiconductor layer, and a plurality of contact pads connected with the wiring patterns. The wiring patterns may include TSVs and traces with fine pitches. The contact pads can provide connectivity for electrical components mounted thereon. The structure and number of the bridge die 146 shown in FIG. 1 are merely for illustration, and the disclosure is not limited thereto. In some other embodiments, other electronic components such as integrated stack capacitors (ISCs), semiconductor dice, semiconductor packages, or discrete devices may be attached on the second side 114 of the first RDL 110. In some embodiments, an underfill may be formed between the bridge die 146 and the second side 114 of the first RDL 110.

As shown in FIG. 1, the first plurality of conductive bumps 148 are formed on the second side 114 of the first RDL 110 and are electrically coupled with contact pads formed on the second side 114 of the first RDL 110. In the example shown in FIG. 1, the first plurality of conductive bumps 148 are illustrated as copper posts, but the present application is not limited thereto. In some other embodiments, the first plurality of conductive bumps 148 may include solder balls, silver balls, e-bar conductive bumps or any other suitable metallic bumps. A second encapsulant 170 is formed on the second side 114 of the first RDL 110. The second encapsulant 170 encapsulates the photonic component 142, the bridge die 146, and the first plurality of conductive bumps 148. The second encapsulant 170 may be made of a polymer composite material, such as epoxy resin with filler, epoxy acrylate with filler, or polymer with proper filler, but the scope of this application is not limited thereto. In the example shown in FIG. 1, the lower surfaces of the photonic component 142, the bridge die 146, and the first plurality of conductive bumps 148 are exposed from the second encapsulant 170. However, the present application is not limited thereto. In some other embodiments, the photonic component 142 and the bridge die 146 may be covered by the second encapsulant 170.

In some embodiments, the second RDL 120 may be similar as the first RDL 110. For example, the second RDL 120 may include one or more dielectric layers and one or more conductive layers between and through dielectric layers, and the conductive layers of the second RDL 120 may form a plurality of contact pads on the first side 122 of the second RDL 120 and also form a plurality of contact pads on the second side 124 of the second RDL 120. A second plurality of conductive bumps 158 are formed on the second side 124 of the second RDL 120 and are electrically coupled with the contact pads formed on the first side 122 of the second RDL 120. The second plurality of conductive bumps 158 may include copper posts, solder balls, silver balls, e-bar conductive bumps or any other suitable metallic bumps.

As shown in FIG. 1, the semiconductor device 100 further includes a substrate 180. The substrate 180 includes a first side 182 and a second side 184 opposite to the first side 182. In some embodiments, the substrate 180 may be made of silicon or other semiconductor materials, and may include other features such as various doped regions, a buried layer, and/or an epitaxy layer. However, the present application is not limited thereto. In some other embodiments, the substrate 180 may include a printed circuit board (PCB), a carrier substrate, a ceramic substrate, a laminate interposer, a strip interposer, a leadframe, or other suitable substrates. The substrate 180 may include any structure on or in which an integrated circuit system can be fabricated. In some examples, the substrate 180 may include redistribution structures having one or more dielectric layers and one or more conductive layers between and through dielectric layers. Thus, the second plurality of conductive bumps 158 may be attached on the first side 182 of the substrate 180 and electrically coupled with contact pads formed by the redistribution structures on the first side 182 of the substrate 180. In some embodiments, an underfill may be formed between the second side 124 of the second RDL 120 and the first side 182 of the substrate 180 to encapsulate the second plurality of conductive bumps 158.

Further, a third plurality of conductive bumps 186 are formed on the second side 184 of the substrate 180. In the example shown in FIG. 1, the third plurality of conductive bumps 186 are illustrated as solder bumps, but the present application is not limited thereto. In some other embodiments, the third plurality of conductive bumps 186 may include copper posts, or any other suitable metallic bumps. In a case where the semiconductor device 100 is mounted on an external device or substrate such as a printed circuit board (PCB), the third plurality of conductive bumps 186 may be used for electrically connecting the semiconductor device 100 to the external device or substrate.

In addition, a stiffener 188 may be attached on the first side 182 of the substrate 180 to improve the rigidity of the semiconductor device 100. For example, the stiffener 188 may be a copper forged lid or a stainless-steel stiffener ring, and is attached on the first side 182 of the substrate 180 via an adhesive. However, the present application is not limited the above embodiment. In some other embodiments, a heat spreader may be attached on the first side 182 of the substrate 180 to form a flip-chip ball grid array package with a heat spreader (fcBGA-H).

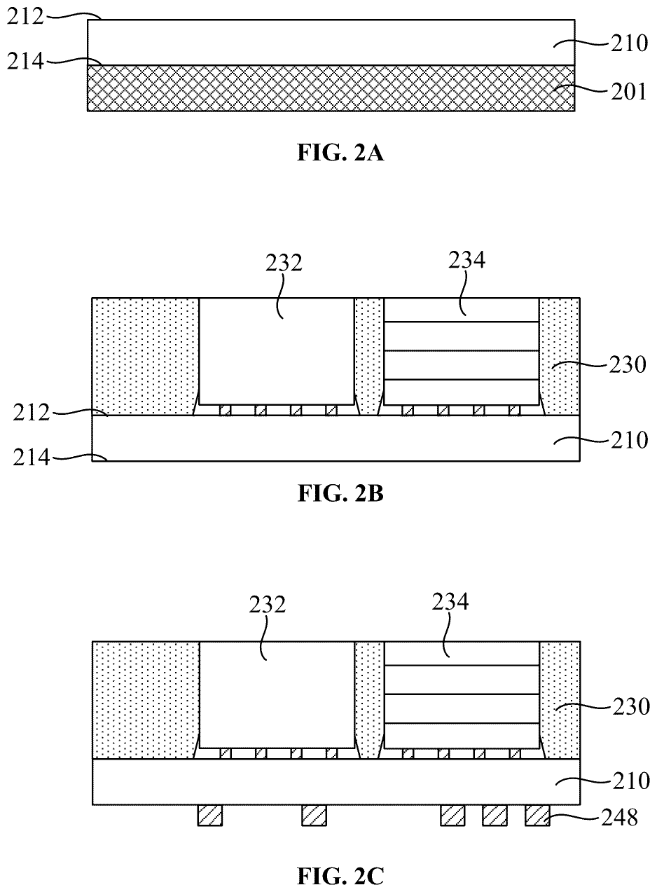

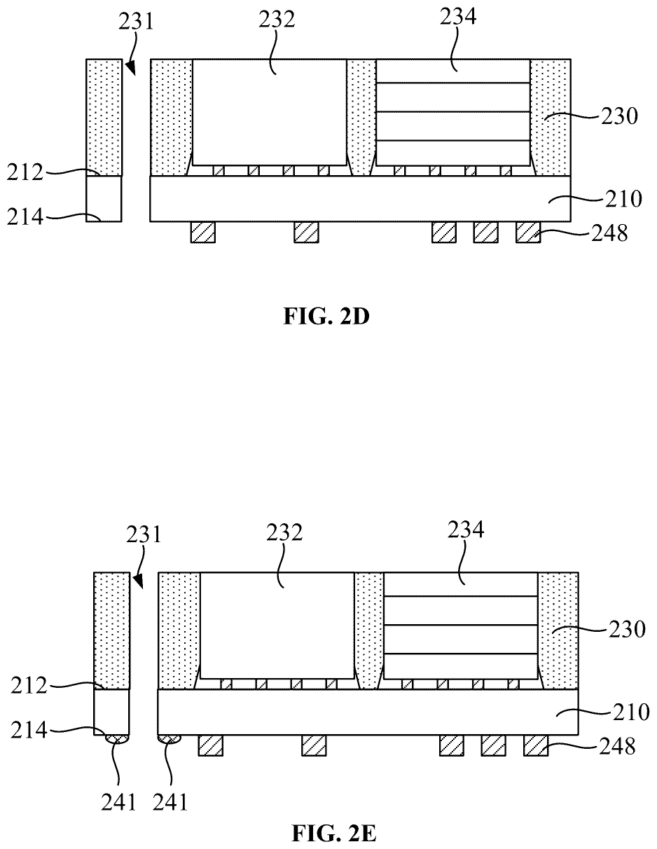

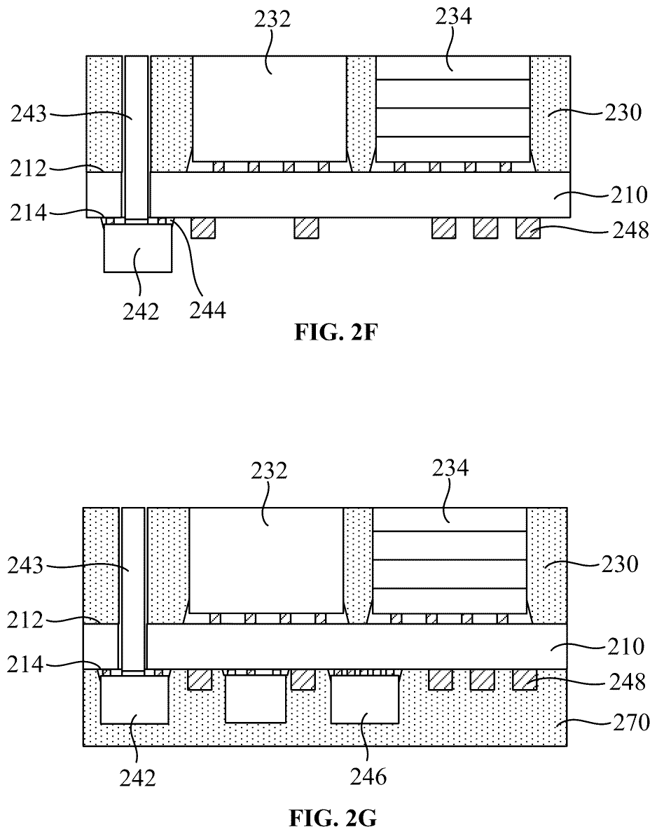

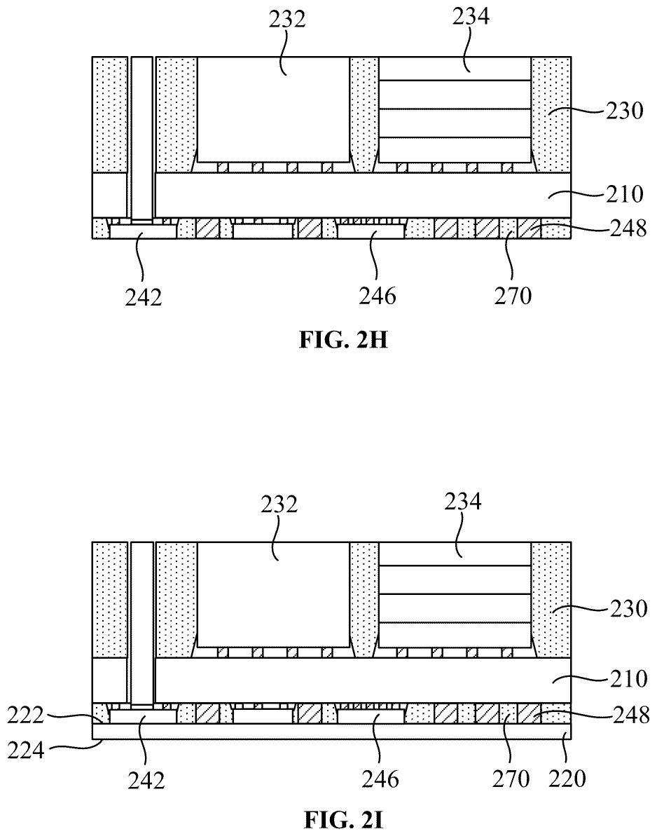

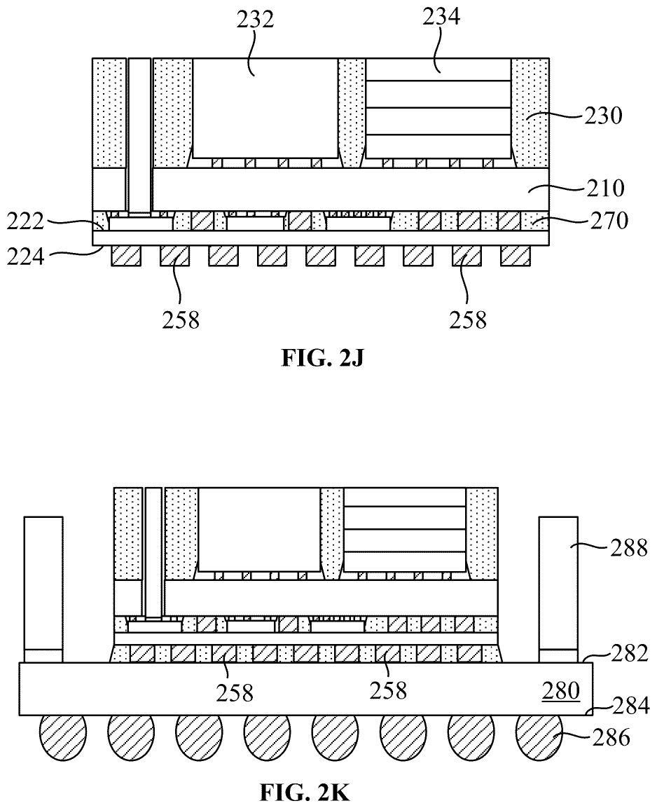

Referring to FIGS. 2A to 2K, cross-sectional views illustrating various steps of a method for forming a semiconductor device are illustrated according to an embodiment of the present application. For example, the method can be used to form the semiconductor device shown in FIG. 1. In the following, the method will be described with reference to FIGS. 2A to 2K in more details.

As shown in FIG. 2A, a first RDL 210 is provided. The RDL 210 includes a first side 212 and a second side 214 opposite to the first side 212.

For example, as shown in FIG. 2A, a carrier 201 may be provided, and then the RDL 210 may be formed on the carrier 201. The carrier 201 may be a glass carrier, a ceramic carrier, or the like. The first RDL 210 may be formed by one or more dielectric layers and one or more conductive layers between and through dielectric layers, and will not be elaborated herein.

Referring to FIG. 2B, at least one electronic component is attached on the first side 212 of the first RDL 210. For example, the at least one electronic component includes a first electronic component 232 and a second electronic component 234 as shown in FIG. 2B. The first electronic component 232 may be System on Chip (SoC) die, and the second electronic component 234 may be a memory die, for example, a high-bandwidth memory (HBM) die, a Dynamic Random Access Memory (DRAM) die, etc. The SoC die is laterally adjacent to the memory die, and a thickness of the SoC die is substantially the same as that of the memory die. In some embodiments, both the SoC die and the memory die are flip-chip bonded to the first side 212 of the first RDL 210.

In some embodiments, an underfill may be formed between the first electronic component 232 and the first side 212 of the first RDL 210, and between the second electronic component 234 and the first side 212 of the first RDL 210 to encapsulate the conductive bumps therebetween. The underfill may include a non-conductive paste (NCP), a molded underfill (MUF), a non-conductive film (NCF), an underfill encapsulant, or a polymer composite material, such as epoxy resin, epoxy acrylate, or polymer with or without a filler. In some examples, the underfill is formed by depositing a fluid material at a location on the first RDL 210 that is next to the first electronic component 232 and the second electronic component 234, and allowing capillary action to draw the fluid material into the space between the first electronic component 232 and the first RDL 210, and the space between the second electronic component 234 and the first RDL 210.

A first encapsulant 230 is formed on the first side 212 of the first RDL 210 to encapsulate the at least one electronic component, i.e., the first electronic component 232 and the second electronic component 234. The first encapsulant 230 may be formed by using compressive molding, transfer molding, liquid encapsulant molding, or other suitable molding processes. The first encapsulant 230 may be made of polymer composite material, such as epoxy resin with filler, epoxy acrylate with filler, or polymer with proper filler, but the scope of this application is not limited thereto.

Then, the first encapsulant 230 is grinded to expose the first electronic component 232 and the second electronic component 234. In some embodiments, a grinder may be used to remove an upper portion of the first encapsulant 230. As the grinding process can planarize a top surface of the entire package, an upper portion of the first electronic component 232 or an upper portion of second electronic component 234 may be removed simultaneously to ensure the top surface of the first electronic component 232 and the top surface of the second electronic component 234 can be substantially flush or coplanar with each other. In some other embodiments, the top surface of the first electronic component 232 and the top surface of the second electronic component 234 are still covered by the first encapsulant 230 after the grinding process.

Referring to FIG. 2C, a first plurality of conductive bumps 248 are formed on the second side 214 of the first RDL 210 to electrically couple with the first RDL 210. In some embodiments, the first plurality of conductive bumps 248 may be copper posts, but the present application is not limited thereto. In some other embodiments, the first plurality of conductive bumps 248 may include solder balls, silver balls, e-bar conductive bumps or any other suitable metallic bumps. In some embodiments, the first plurality of conductive bumps 248 are formed by depositing (e.g., sputtering or plating) one or more layers of conductive material on the second side 214 of the first RDL 210. In some embodiments, the first plurality of conductive bumps 248 are formed on the second side 214 of the first RDL 210 using a surface mounting technique.

Referring to FIG. 2D, a through hole 231 is formed in the first encapsulant 230 and the first RDL 210. For example, the through hole 231 is formed through the first encapsulant 230 and the first RDL 210 using laser drilling, mechanical drilling, deep reactive ion etching (DRIE), or other suitable process. In some embodiments, a cleaning process may be performed to remove dust and debris formed during the drilling process.

Referring to FIG. 2E, soldering flux 241 may be formed on one or more contact pads formed on the second side 214 of the first RDL 210. The one or more contact pads are located near the through hole 231 and are configured for electrically connecting with a photonic component in subsequent steps. The soldering flux 241 may facilitate reflowing of solder materials onto the pads. In some embodiments, the soldering flux 241 may be formed on the contact pads on the second side 214 of the first RDL 210 by using a printing process. For example, a stencil may be used to print the soldering flux 241 at desired locations, i.e., on the contact pads for the photonic component. However, the present application is not limited to the above embodiments, and the soldering flux 241 can be formed by other suitable techniques.

Referring to FIG. 2F, a photonic component 242 is attached on the second side 214 of the first RDL 210.

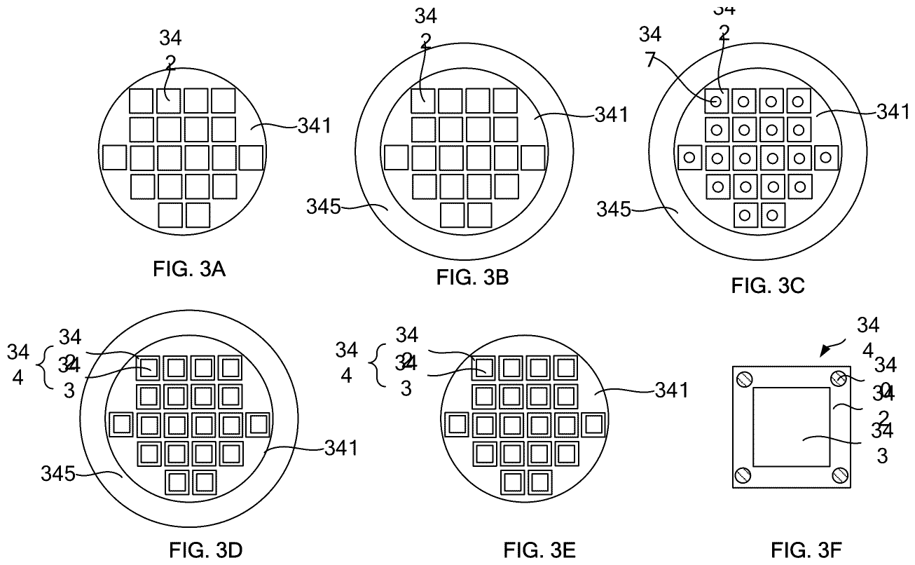

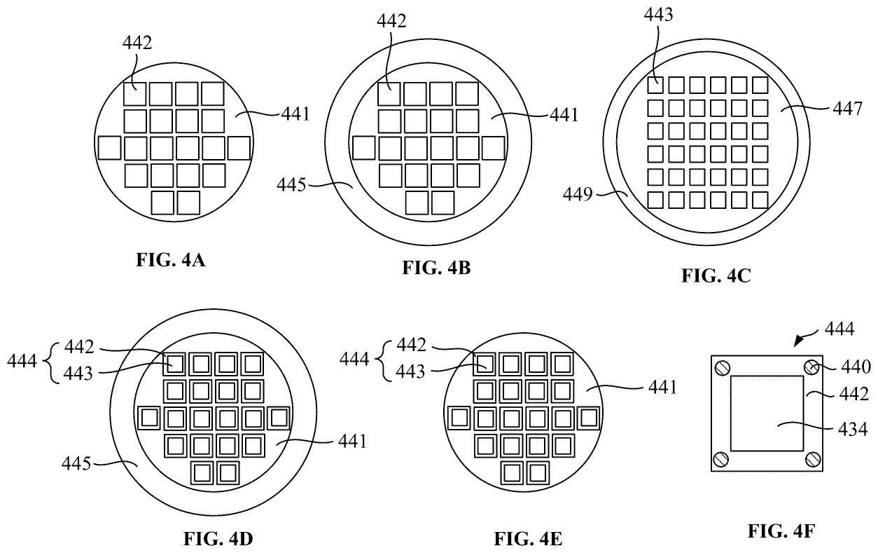

In some embodiments, a photonic assembly including the photonic component 242 and a glass lens 243 attached on the photonic component 242 is provided. For example, the glass lens 243 may be attached on the photonic component 242 via a transparent adhesive or a transparent die attach film (DAF). More details about the photonic assembly may be discussed with reference to FIGS. 3A to 3F and FIGS. 4A to 4F hereafter.

Referring to both FIGS. 2E and 2F, the glass lens 243 may be inserted into the through hole 231, and conductive bumps such as solder balls of the photonic component 242 may be mounted on the contact pads formed on the second side 214 of the first RDL 210 with the aid of the soldering flux 241. Thus, the glass lens 243 may extend through the through hole 231, and an upper surface of the glass lens 243 is exposed from the first encapsulant 230. In the example shown in FIG. 2F, there may be a gap left between the glass lens 243 and the first encapsulant 230 to facilitate insertion of the glass lens 243. However, the present application is not limited thereto. The photonic component 242 may be a photonic integrated circuit (PIC), which has the capability to transmit and/or receive light signals, and the glass lens 243 can carry the light signals to and/or from the photonic component 242.

In some embodiments, an underfill 244 may be formed between the photonic component 242 and the first RDL 210. For example, the underfill 244 may include a non-conductive paste (NCP). However, the present application is not limited thereto. In some other examples, the underfill 244 may include a molded underfill (MUF), a non-conductive film (NCF), an underfill encapsulant, or a polymer composite material.

Referring to FIG. 2G, at least one bridge die 246 is attached on the second side 214 of the first RDL 210 to electrically couple the first electronic component 232 with the second electronic component 234. In some embodiments, soldering flux may be formed on the contact pads where the bridge die 246 is to be attached. For example, a flux printing process or a flux dipping process may be used to form the soldering flux. Then, the bridge die 246 may be placed over and electrically connected to the contact pads formed on the second side 214 of the first RDL 210 via conductive bumps. The bridge die 246 may be made of semiconductor material, glass, or organic materials with redistribution layers or wiring patterns formed therein. Preferably, the bridge die 246 is a silicon-based interposer (also known as a silicon bridge). The bridge die 246 may be fabricated using any suitable IC manufacturing processes and can offer various advantages. For example, the bridge die 246 can support fine pitches for through-silicon vias (TSVs) and traces used in signal and power distribution, and may have a thermal expansion coefficient which can match that of the semiconductor die it is in contact with. In some embodiments, an underfill may be formed between the bridge die 246 and the first RDL 210. In some embodiments, other electronic components such as integrated stack capacitors, semiconductor dice, semiconductor packages, or discrete devices may also be attached on the second side 214 of the first RDL 210.

Afterwards, continuing referring to FIG. 2G, a second encapsulant 270 is formed on the second side 214 of the first RDL 210 to encapsulate the photonic component 242, the bridge die 246 and the first plurality of conductive bumps 248. The second encapsulant 270 may be formed by using compressive molding, transfer molding, liquid encapsulant molding, or other suitable molding processes. The second encapsulant 270 may be made of polymer composite material, such as epoxy resin with filler, epoxy acrylate with filler, or polymer with proper filler, but the scope of this application is not limited thereto.

Referring to FIG. 2H, the second encapsulant 270 is grinded to expose the first plurality of conductive bumps 248. In some embodiments, a grinder may be used to remove an upper portion of the second encapsulant 270. In some embodiments, as the grinding process can planarize a top surface of the entire package, a lower portion of the photonic component 242, a lower portion of the bridge die 246 and lower portions of the first plurality of conductive bumps 248 may be removed simultaneously to ensure the lower surface of the photonic component 242, the lower surface of the bridge die 246 and lower surfaces of the first plurality of conductive bumps 248 can be substantially flush or coplanar with each other. In some other embodiments, the lower surface of the photonic component 242 and the lower surface of the bridge die 246 are still covered by the second encapsulant 270 after the grinding process.

Referring to FIG. 2I, a second RDL 220 is provided, and the second RDL 220 may include a first side 222 and a second side 224 opposite to the first side 222. Then, the first plurality of conductive bumps 248 are electrically coupled to the first side 222 of the second RDL 220. In some embodiments, the second RDL 220 may be similar as the first RDL 210. For example, the second RDL 220 may include one or more dielectric layers and one or more conductive layers between and through dielectric layers, and the conductive layers of the second RDL 220 may form a plurality of contact pads on the first side 222 of the second RDL 220 and form a plurality of contact pads on the second side 224 of the second RDL 220. The first plurality of conductive bumps 248 may be mounted on the plurality of contact pads on the second side 224 of the second RDL 220.

Referring to FIG. 2J, a second plurality of conductive bumps 258 are formed on the second side 224 of the second RDL 220 to electrically couple with the second RDL 220. In some embodiments, the second plurality of conductive bumps 258 may be copper posts, but the present application is not limited thereto. In some other embodiments, the second plurality of conductive bumps 258 may include solder balls, silver balls, e-bar conductive bumps or any other suitable metallic bumps.

Afterwards, referring to FIG. 2K, a substrate 280 is provided, and the substrate 280 includes a first side 282 and a second side 284 opposite to the first side 282. The second plurality of conductive bumps 258 is attached on the first side 282 of the substrate 280.

In some embodiments, the substrate 280 may include a semiconductor substrate, a PCB, a carrier substrate, a ceramic substrate, a laminate interposer, a strip interposer, a leadframe, or other suitable substrates. In some examples, the substrate 280 may include redistribution structures having one or more dielectric layers and one or more conductive layers between and through dielectric layers. Thus, the second plurality of conductive bumps 258 may be attached on the first side 282 of the substrate 280 and electrically coupled with contact pads formed by the redistribution structures on the first side 282 of the substrate 280. In some embodiments, an underfill may be formed between the second side 224 of the second RDL 220 and the first side 282 of the substrate 280 to encapsulate the second plurality of conductive bumps 258.

Then, a third plurality of conductive bumps 286 are formed on the second side 284 of the substrate 280. In the example shown in FIG. 2K, the third plurality of conductive bumps 286 are illustrated as solder bumps, but the present application is not limited thereto. In some other embodiments, the third plurality of conductive bumps 286 may include copper posts, or any other suitable metallic bumps.

In the example shown in FIG. 2K, a stiffener 288 may be attached on the first side 282 of the substrate 280 to improve the rigidity of the semiconductor device. For example, the stiffener 288 may be a copper forged lid or a stainless-steel stiffener ring, and is attached on the first side 282 of the substrate 280 via an adhesive. However, the present application is not limited the above embodiment. In some other embodiments, a heat spreader may be attached on the first side 282 of the substrate 280 to form a flip-chip ball grid array package with a heat spreader (fcBGA-H).

In the examples of FIG. 2A to FIG. 2K, it is only illustrated a single unit of semiconductor device, but the present application is not limited thereto. Usually, a wafer level or strip type of semiconductor devices, i.e., a plurality of semiconductor devices arranged in a strip manner, may be provided. The plurality of semiconductor devices may be isolated from each other by singulation channels. The wafer level or strip type of semiconductor devices may be singulated into individual semiconductor devices along the singulation channels.

Referring to FIGS. 3A to 3F, top views illustrating various steps of a method for forming a photonic assembly are illustrated according to another embodiment of the present application. For example, the method can also be used to form the photonic assembly including the photonic component 242 and the glass lens 243 as shown in FIG. 2E.

As shown in FIG. 3A, a photonic wafer 341 is provided. The photonic wafer 341 may include a plurality of photonic components 342 arranged in an array. The plurality of photonic components 342 may be isolated from each other by singulation channels. In some examples, a diameter of the photonic wafer is 8 inches. In some examples, one or more conductive bumps may be formed in a peripheral area of each photonic component 342. In FIG. 3B, the photonic wafer 341 is mounted on a carrier 345 (also referred to as a singulation carrier in the present application), for example, by an adhesive or a jig. The carrier 345 may be a glass carrier, a ceramic carrier, or the like. For example, the carrier 345 is a glass wafer having a diameter of 12 inches, such that subsequent processes can be performed using 12-inch wafer infrastructure. In FIG. 3C, an adhesive 347 is dispensed on each of the plurality of photonic components 342. The adhesive 347 should be transparent, such that the light signals to and/or from the photonic component 342 can pass through. In FIG. 3D, a glass lens 343 is attached on each of the plurality of photonic components 342 via the adhesive 347, so as to form a photonic assembly 344. In some examples, the glass lens 343 may be attached on a central area of each photonic component 342, where no conductive bump is formed. Afterwards, in FIG. 3E, the carrier 345 is detached from the photonic wafer 341, and the photonic wafer 341 is singulated into a plurality of individual photonic assemblies 344. For example, the photonic wafer 341 may be mounted on a ring frame, and a tape is adhered onto the ring frame to hold the photonic wafer 341 in place. Then, a sawing process is performed on the photonic wafer 341 to singulate the photonic wafer 341 into a plurality of individual photonic assemblies 344. An enlarged view of an exemplary photonic assembly 344 is illustrated in FIG. 3F, in which the conductive bumps 340 are formed in the peripheral area of the photonic component 342, and the glass lens 343 is attached on the central area of the photonic component 342. The photonic assembly 344 may be further used to form a semiconductor package. Similar as the example illustrated in FIG. 2F, the photonic component 342 of the photonic assembly 344 may be mounted on the second side of the first RDL using a chip-on-wafer (CoW) flip-chip bonding technology to form a semiconductor package. It could be understood that, the sizes and/or the shapes of various components in the above embodiment may be exemplary only, and are not restrictive of the invention.

Referring to FIGS. 4A to 4F, top views illustrating various steps of a method for forming a photonic assembly are illustrated according to another embodiment of the present application. For example, the method can also be used to form the photonic assembly including the photonic component 242 and the glass lens 243 as shown in FIG. 2E.

As shown in FIG. 4A, a photonic wafer 441 is provided. The photonic wafer 441 may include a plurality of photonic components 442 arranged in an array. In some examples, a diameter of the photonic wafer 441 is 8 inches. In some examples, one or more conductive bumps may be formed in a peripheral area of each photonic component 442. In FIG. 4B, the photonic wafer 441 is mounted on a carrier 445 (also referred to as a singulation carrier in the present application). In some examples, the carrier 445 may be a ring frame which is widely used for wafer mounting or wafer sawing, and a tape is adhered onto the ring frame to hold the photonic wafer 441 in place. The ring frame may be adapted for mounting a wafer having a diameter of 12 inches, and subsequent processes can be performed using 12-inch wafer infrastructure. In FIG. 4C, a die attach film (DAF) 447 is provided, and a plurality of glass lenses 443 is mounted on the DAF 447 in an array. Then, the DAF 447 may be mounted on another carrier 449 such as a glass carrier or a ceramic carrier, and then is singulated, such that each of the plurality of glass lenses 443 has an individual DAF 447 attached thereon. In FIG. 4D, each of the plurality of glass lenses 443 is attached on a respective one of the plurality of photonic components 442 via the individual DAF 447. In some examples, the glass lens 443 may be attached on a central area of each photonic component 442, where no conductive bump is formed. The DAF 447 should be transparent, such that the light signals to and/or from the photonic component 442 can pass through. Afterwards, in FIG. 4E, a sawing process is performed on the photonic wafer 441 to singulate the photonic wafer 441 into a plurality of individual photonic assemblies 444. After the sawing process, the plurality of individual photonic assemblies 444 may be detached from the carrier 445. An enlarged view of an exemplary photonic assembly 444 is illustrated in FIG. 4F, in which the conductive bumps 440 are formed in the peripheral area of the photonic component 442, and the glass lens 443 is attached on the central area of the photonic component 442.

It could be understood that, the sizes and/or the shapes of various components in the above embodiment may be exemplary only, and are not restrictive of the invention. In another embodiment, a diameter of the photonic wafer 441 is 12 inches, and the carrier 445 may be a ring frame adapted for mounting a wafer having a diameter of 12 inches. When the photonic assembly 444 is used to form the semiconductor package illustrated in FIG. 2F, the photonic component 442 of the photonic assembly 444 may be mounted on the second side of the first RDL using a CoW flip-chip bonding technology, or a CoW surface mount technology (SMT), or a CoW flip chip attach (FCA) technology. In another embodiment, a diameter of the photonic wafer 441 is 8 inches, and the carrier 445 may be a ring frame adapted for mounting a wafer having diameter of 8 inches. When the photonic assembly 444 is used to form the semiconductor package illustrated in FIG. 2F, the plurality of individual photonic assemblies 444 may be first attached onto a reel using a tape and reel (T&R) packaging technology, and then the photonic component 442 of each photonic assembly 444 may be mounted on the second side of the first RDL using a surface mount technology (SMT). In still another embodiment, a diameter of the photonic wafer 441 is 12 inches, and the carrier 445 may be a ring frame adapted for mounting a wafer having diameter of 12 inches. When the photonic assembly 444 is used to form the semiconductor package illustrated in FIG. 2F, the plurality of individual photonic assemblies 444 may be first attached onto a reel using a tape and reel packaging technology, and then the photonic component 442 of each photonic assembly 444 may be mounted on the second side of the first RDL using a surface mount technology (SMT).

The discussion herein included numerous illustrative figures that showed various portions of a semiconductor device and a method for forming the semiconductor device. For illustrative clarity, such figures did not show all aspects of each example devices. Any of the example devices and/or methods provided herein may share any or all characteristics with any or all other devices and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor device, comprising:
a first redistribution layer (RDL) having a first side and a second side opposite to the first side;
at least one electronic component attached on the first side of the first RDL;
a photonic component attached on the second side of the first RDL;
a first plurality of conductive bumps formed on the second side of the first RDL and electrically coupled with the first RDL;
a second RDL having a first side and a second side opposite to the first side, wherein the first side of the second RDL is electrically coupled with the first plurality of conductive bumps; and
a second plurality of conductive bumps formed on the second side of the second RDL and electrically coupled with the second RDL.

2. The semiconductor device of claim 1, wherein the at least one electronic component comprises a first electronic component and a second electronic component, and the semiconductor device further comprises:
a bridge die attached on the second side of the first RDL and configured for electrically coupling the first electronic component with the second electronic component.

3. The semiconductor device of claim 1, further comprising:
a first encapsulant formed on the first side of the first RDL and encapsulating the at least one electronic component; and
a second encapsulant formed on the second side of the first RDL and encapsulating the photonic component.

4. The semiconductor device of claim 3, further comprising:
a glass lens formed in a through hole extending through the first RDL and the first encapsulant, wherein the glass lens is optically coupled with the photonic component.

5. The semiconductor device of claim 1, further comprising:
a substrate having a first side and a second side opposite to the first side, wherein the first side of the substrate is electrically coupled with the second plurality of conductive bumps; and
a third plurality of conductive bumps formed on the second side of the substrate.

6. The semiconductor device of claim 5, further comprising:
a stiffener or a heat spreader attached on the first side of the substrate.

7. A method for forming a semiconductor device, comprising:
providing a carrier;
forming a first redistribution layer (RDL) on the carrier, the first RDL having a first side and a second side opposite to the first side;
attaching at least one electronic component on the first side of the first RDL;
forming a first encapsulant on the first side of the first RDL to encapsulate the at least one electronic component;
forming a first plurality of conductive bumps on the second side of the first RDL to electrically couple with the first RDL;
forming a through hole through the first encapsulant and the first RDL;
providing a photonic assembly comprising a photonic component and a glass lens attached on the photonic component;
attaching the photonic component on the second side of the first RDL with the glass lens extending through the through hole;
coupling the first plurality of conductive bumps to a first side of a second RDL; and
forming a second plurality of conductive bumps on a second side of the second RDL to electrically couple with the second RDL, wherein the second side of the second RDL is opposite to the first side of the second RDL.

8. The method of claim 7, further comprising:
grinding the first encapsulant to expose the at least one electronic component.

9. The method of claim 7, wherein providing the photonic assembly comprises:
providing a photonic wafer comprising a plurality of photonic components;
mounting the photonic wafer on a singulation carrier;
dispensing an adhesive on each of the plurality of photonic components;
attaching a glass lens on each of the plurality of photonic components via the adhesive; and
singulating the photonic wafer into a plurality of individual photonic assemblies.

10. The method of claim 9, wherein a diameter of the photonic wafer is 8 inches, and the singulation carrier is a glass wafer having a diameter of 12 inches, and wherein attaching the photonic component on the second side of the first RDL comprises:
mounting the photonic component of the photonic assembly on the second side of the first RDL using a chip-on-wafer (CoW) flip-chip bonding technology.

11. The method of claim 7, wherein providing the photonic assembly comprises:
providing a photonic wafer comprising a plurality of photonic components;
mounting the photonic wafer on a singulation carrier which has a diameter larger than that of the photonic wafer;
mounting a plurality of glass lenses on a die attach film;
singulating the die attach film such that each of the plurality of glass lenses has an individual die attach film attached thereon;
attaching each of the plurality of glass lenses on a respective one of the plurality of photonic components via the individual die attach film;
singulating the photonic wafer into a plurality of individual photonic assemblies; and
detaching the plurality of individual photonic assemblies from the singulation carrier.

12. The method of claim 11, wherein a diameter of the photonic wafer is 8 inches or 12 inches, and the individual photonic assembly is tape-and-reel (T&R) packed and is attached on the second side of the first RDL using a chip-on-wafer (CoW) surface mount technology (SMT).

13. The method of claim 11, wherein a diameter of the photonic wafer is 12 inches, the individual photonic assembly is attached on the second side of the first RDL using a chip-on-wafer (CoW) flip-chip attach (FCA) technology.

14. The method of claim 11, wherein a diameter of the photonic wafer is 12 inches, and the singulation carrier is a ring frame adapted for mounting a wafer having a diameter of 12 inches, and wherein attaching the photonic component on the second side of the first RDL comprises:
mounting the photonic component of the photonic assembly on the second side of the first RDL using a chip-on-wafer (CoW) flip-chip bonding technology.

15. The method of claim 11, wherein a diameter of the photonic wafer is 8 inches or 12 inches, and the singulation carrier is a ring frame adapted for mounting a wafer having a diameter of 8 inches or 12 inches, and wherein attaching the photonic component on the second side of the first RDL comprises:
attaching the plurality of individual photonic assemblies onto a reel using a tape and reel packaging technology; and
mounting the photonic component of the photonic assembly on the second side of the first RDL using a surface mount technology (SMT).

16. The method of claim 7, wherein the at least one electronic component comprises a first electronic component and a second electronic component, and the method further comprises:
attaching a bridge die on the second side of the first RDL to electrically couple the first electronic component with the second electronic component.

17. The method of claim 7, further comprising:
forming a second encapsulant on the second side of the first RDL to encapsulate the photonic component and the first plurality of conductive bumps; and
grinding the second encapsulant to expose the first plurality of conductive bumps.

18. The method of claim 7, further comprising:
attaching the second plurality of conductive bumps on a first side of a substrate; and
forming a third plurality of conductive bumps on a second side of the substrate, wherein the second side of the substrate is opposite to the first side of the substrate.

19. The method of claim 18, further comprising:
attaching a stiffener or a heat spreader on the first side of the substrate.
